(19) United States
(12) Patent Application Publication
(10) Pub. No.: US 2021/0223900 A1
(43) Pub. Date: Jul. 22, 2021

(54) MULTIPLE STRAIN SENSORS CONFIGURED FOR COLLECTIVE TOUCH INPUT DETECTION

(71) Applicant: Sentons Inc., Grand Cayman (KY)

(72) Inventor: Samuel W. Sheng, Saratoga, CA (US)

(21) Appl. No.: 17/167,687

(22) Filed: Feb. 4, 2021

Related U.S. Application Data
(63) Continuation-in-part of application No. 16/101,238, filed on Aug. 10, 2018.
(60) Provisional application No. 62/982,689, filed on Feb. 27, 2020.
(60) Provisional application No. 62/545,391, filed on Aug. 14, 2017.

(51) Int. Cl. G06F 3/041

(52) U.S. Cl. CPC G06F 3/0414

(57) ABSTRACT

A technique for sensing touch inputs to a device is described. Measurements are received from a plurality of force sensors. The measurements are compared to a signature corresponding to at least one input force applied to at least one of a plurality of regions configured to receive a force. It is determined that a correlation between the measurements and the signature exceeds a threshold. A touch input is detected in response to the determination.

### CROSS REFERENCE TO OTHER APPLICATIONS

This application claims priority to U.S. Provisional Patent Application No. 62/982,689 entitled MULTIPLE STRAIN SENSORS CONFIGURED FOR COLLECTIVE TOUCH INPUT DETECTION filed Feb. 27, 2020 which is incorporated herein by reference for all purposes.

### BACKGROUND OF THE INVENTION

Various electrical components can be used to detect a physical disturbance (e.g., strain, force, pressure, vibration, etc.) and provide a corresponding signal. For example, a component may detect expansion of or pressure on a particular region on a device and provide an output signal in response. Such components may be utilized in devices to detect a touch. For example, a component mounted on a portion of the mobile phone may detect an expansion or flexing of the portion to which the component is mounted and provide an output signal. The output signal from the component can be considered to indicate a purposeful touch (a touch input) of the mobile phone by the user. However, a mobile phone may undergo flexing and/or localized pressure increases for reasons not related to a user's touch. In addition, a user touching other regions of the mobile phone may result in an expansion and/or local pressure increase of the portion to which the component is connected. Such situations can result in false detections of touch inputs. Other situations in which a user purposefully touches a region of the mobile device may not result in detection of a touch input. Consequently, an improved mechanism for accurately detecting touch input is desired.

### BRIEF DESCRIPTION OF THE DRAWINGS

Various embodiments of the invention are disclosed in the following detailed description and the accompanying drawings.

FIG. 1 is a schematic diagram illustrating an embodiment of a piezoresistive bridge structure usable as a strain sensor.

FIG. 2 depicts an embodiment of an integrated sensor.

FIG. 3 is a block diagram illustrating an embodiment of a system for detecting a touch inputs.

FIG. 4 is a flow chart depicting an embodiment of a method for detecting touch inputs using force sensors.

FIG. 5 is a flow chart depicting an embodiment of a method for detecting touch inputs using force sensors.

FIG. 6 is a flow chart depicting an embodiment of a method utilizing strain sensors for performing touch input detection.

FIGS. 7A-7D are diagrams depicting embodiments of a device utilizing strain sensors for providing touch detection.

FIG. 8 is a flow chart depicting an embodiment of a method for detecting touch inputs using force sensors.

FIG. 9 depicts an embodiment of a device utilizing strain sensors for touch detection.

FIG. 10 is a flow chart depicting an embodiment of a method for providing a signature.

### DETAILED DESCRIPTION

The invention can be implemented in numerous ways, including as a process; an apparatus; a system; a composition of matter; a computer program product embodied on a computer readable storage medium; and/or a processor, such as a processor configured to execute instructions stored on and/or provided by a memory coupled to the processor. In this specification, these implementations, or any other form that the invention may take, may be referred to as techniques. In general, the order of the steps of disclosed processes may be altered within the scope of the invention. Unless stated otherwise, a component such as a processor or a memory described as being configured to perform a task may be implemented as a general component that is temporarily configured to perform the task at a given time or a specific component that is manufactured to perform the task. As used herein, the term ‘processor’ refers to one or more devices, circuits, and/or processing cores configured to process data, such as computer program instructions.

A detailed description of one or more embodiments of the invention is provided below along with accompanying figures that illustrate the principles of the invention. The invention is described in connection with such embodiments, but the invention is not limited to any embodiment. The scope of the invention is limited only by the claims and the invention encompasses numerous alternatives, modifications and equivalents. Numerous specific details are set forth in the following description in order to provide a thorough understanding of the invention. These details are provided for the purpose of example and the invention may be practiced according to the claims without some or all of these specific details. For the purpose of clarity, technical material that is known in the technical fields related to the invention has not been described in detail so that the invention is not unnecessarily obscured.

User touches of a device such as a mobile phone (e.g. a smart phone) or touch screen are desired to be detected. Further, purposeful touches by a user are desired to be distinguished from inadvertent touches. For example, a swipe or press of a particular region of a mobile phone is desired to be distinguished from a user sitting on the phone. The swipe or press should be detected as touch inputs, while the user sitting on the phone should not be determined to be a touch input. A touch input results from input forces provided by the user on the device. In response to the input forces, portions of the device may expand or flex. Consequently, touch inputs and the corresponding input forces applied to the device may be detected by detecting expansions or flexing of the device.

A system for detecting touch inputs applied to a device includes force sensors, a processor and a memory that stores instructions and is coupled to the processor. The force sensors include strain sensors. Each force sensor may be an integrated sensor including multiple strain sensors and a temperature sensor. The strain sensors are configured to detect strains in different directions. In some embodiments, the integrated sensors are mounted to the frame of the device, such as the midframe of a mobile phone.

Measurements (e.g. strain measurements) are received from the force sensors. The measurements are compared to a signature corresponding to input force(s) applied to regions configured to receive forces. If a correlation between the measurements and the signature exceeds a threshold, then a touch input is detected. In some embodiments, the signature is a precalibrated vector corresponding to calibration force(s) applied to the regions. For example, the precalibrated vector may be a normalized set of averaged strain measurements output by the force sensors in response to user touch inputs provided during calibration. In such embodiments, the strain measurements received are compared to the precalibrated vector. The touch input, or other physical disturbance is detected if the strain measurements are sufficiently correlated with the precalibrated vector. In some embodiments, the signature is a precalibrated force transfer matrix. The precalibrated force transfer matrix is used to map the strain measurements to input force(s) applied to the region(s). Based upon the magnitude and location of the force, a touch input or other physical disturbance.

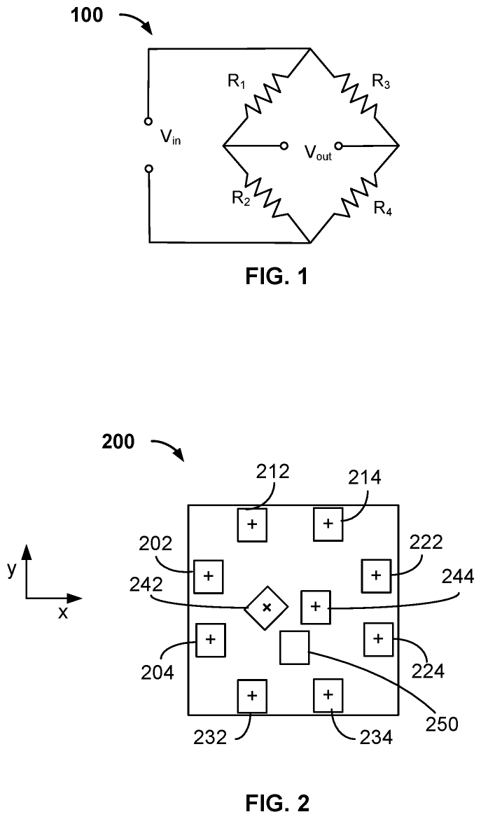

FIG. 1 is a schematic diagram illustrating an embodiment of a piezoresistive bridge structure that can be utilized as a strain sensor. Piezoresistive bridge structure 100 includes four piezoresistive elements that are connected together as two parallel paths of two piezoresistive elements in series (e.g., Wheatstone Bridge configuration). Each parallel path acts as a separate voltage divider. The same supply voltage (e.g., Vᵢₙ of FIG. 1) is applied to both of the parallel paths. By measuring a voltage difference (e.g., Vₒᵤₜ of FIG. 1) between a mid-point at one of the parallel paths (e.g., between piezoresistive elements R₁ and R₂ in series as shown in FIG. 1) and a mid-point of the other parallel path (e.g., between piezoresistive elements R₃ and R₄ in series as shown in FIG. 1), a magnitude of a physical disturbance (e.g. strain) applied on the piezoresistive structure can be detected.

In some embodiments, rather than individually attaching separate already manufactured piezoresistive elements together on to a backing material to produce the piezoresistive bridge structure, the piezoresistive bridge structure is manufactured together as a single integrated circuit component and included in an application-specific integrated circuit (ASIC) chip. For example, the four piezoresistive elements and appropriate connections between are fabricated on the same silicon wafer/substrate using a photolithography microfabrication process. In an alternative embodiment, the piezoresistive bridge structure is built using a microelectromechanical systems (MEMS) process. The piezoresistive elements may be any mobility sensitive/dependent element (e.g., as a resistor, a transistor, etc.).

FIG. 2 is a block diagram depicting an embodiment of integrated sensor 200 that can be used to sense forces (e.g. a force sensor). In particular, forces input to a device may result in flexing of, expansion of, or other physical disturbance in the device. Such physical disturbances may be sensed by force sensors. Integrated sensor 200 includes multiple strain sensors 202, 204, 212, 214, 222, 224, 232, 234, 242 and 244. Each strain sensor 202, 204, 212, 214, 222, 224, 232, 234, 242 and 244 may be a piezoresistive element such as piezoresistive element 100. In other embodiments, another strain measurement device might be used. Strain sensors 202, 204, 212, 214, 222, 224, 232, 234, 242 and 244 may be fabricated on the same substrate. Multiple integrated sensors 200 may also be fabricated on the same substrate and then singulated for use. Integrated sensor 200 may be small, for example five millimeters by five millimeters (in the x and y directions) or less.

Each strain sensor 202, 204, 212, 214, 222, 224, 232, 234, 242 and 244 is labeled with a + sign indicating the directions of strain sensed. Thus, strain sensors 202, 204, 212, 214, 222, 224, 232, 234 and 244 sense strains (expansion or contraction) in the x and y directions. However, strain sensors at the edges of integrated sensor 200 may be considered to sense strains in a single direction. This is because there is no expansion or contraction beyond the edge of integrated sensor 200. Thus, strain sensors 202 and 204 and strain sensors 222 and 224 measure strains parallel to the y-axis, while strain sensors 212 and 214 and strain sensors 232 and 234 sense strains parallel to the x-axis. As can be seen in FIG. 2, strain sensor 242 has been configured in a different direction. Thus, strain sensor 242 measures strains in the xy direction (parallel to the lines x=y or x=−y). For example, strain sensor 242 may be used to sense twists of integrated sensor 200. In some embodiments, the output of strain sensor 242 is small or negligible in the absence of a twist to integrated sensor 200 or the surface to which integrated sensor 200 is mounted.

Thus, integrated sensor 200 obtains ten measurements of strain: four measurements of strain in the y direction from strain sensors 202, 204, 222 and 224; four measurements of strain in the x direction from sensors 212, 214, 232 and 234; one measurement of strains in the xy direction from sensors 242 and one measurement of strain from sensor 244. Although ten strain measurements are received from strain sensors 202, 204, 212, 214, 222, 224, 232, 234, 242 and 244, six measurements may be considered independent. Strain sensors 202, 204, 212, 214, 222, 224, 232, and 234 on the edges may be considered to provide four independent measurements of strain. In other embodiments, a different number of strain sensors and/or different locations for strain sensors may be used in integrated sensor 200. Multiple sensors oriented in the same axis can also be used to determine if there is nonuniformity or defects in the sensor or the surface to which integrated sensor 200 is mounted, since discrepancies in readings between sensors with the same axial orientation may be indicative of such.

Integrated sensor 200 also includes temperature sensor 250 in some embodiments. Temperature sensor 250 provide an onboard measurement of the temperatures to which strain sensors 202, 204, 212, 214, 222, 224, 232, 234, 242 and 244 are exposed. Thus, temperature sensor 200 may be used to account for drift and other temperature artifacts that may be present in strain data. Integrated sensor 200 may be used in a device for detecting touch inputs.

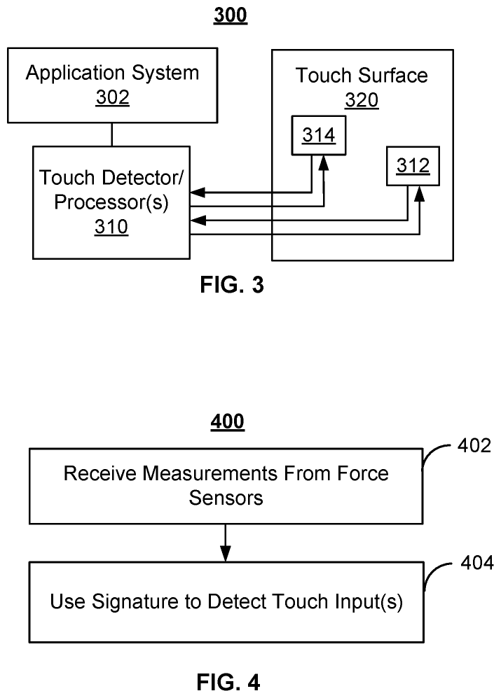

FIG. 3 is a block diagram illustrating an embodiment of system 300 for detecting a touch input. System 300 may be considered part of a device utilizing touch inputs. Thus, system 300 may be part of a kiosk, an ATM, a computing device, an entertainment device, a digital signage apparatus, a mobile phone, a tablet computer, a point of sale terminal, a food and restaurant apparatus, a gaming device, a casino game and application, a piece of furniture, a vehicle, an industrial application, a financial application, a medical device, an appliance, and any other objects or devices having surfaces for which a touch input is desired to be detected.

System 300 is connected with application system 302 and touch surface 320, which may be considered part of the device with which system 300 is used. System 300 includes touch detector 310 and force sensors 312 and 314. For simplicity, only some portions of system 300 are shown. Touch surface 320 is a surface on which touch inputs are desired to be detected. For example touch surface may include the display of a mobile phone, the touch screen of a laptop, an edge of a mobile phone, a portion of the frame of the device or other surface. Force sensors 312 and 314 may be integrated sensors including multiple strain sensors, such as integrated sensor 200. In other embodiments, force sensors 312 and 314 may be an individual strain sensor. Although two force sensors 312 and 314 are shown, another number is typically present. Application system 302 may include the operating system for the device in which system 300 is used.

In some embodiments, touch detector 310 is integrated in an integrated circuit chip. Touch detector 310 includes one or more microprocessors that process instructions and/or calculations that can be used to program software/firmware and/or process data for touch detector 310. In some embodiments, touch detector 310 include a memory coupled to the microprocessor and configured to provide the microprocessor with instructions. Other components such as digital signal processors may also be used.

Touch detector 310 receives input from force sensors 312 and 314 and may provide signals and/or power to force sensors 312 and 314. For example, touch detector 310 receives strain measurements from force sensors 312 and 314 and may provide the input voltage(s) to force sensors 312 and 314. Touch detector 310 utilizes the strain measurements to determine whether a user has provided touch input touch surface 320. If a touch input is detected, touch detector 310 provides this information to application system 302 for use.

Signals provided from force sensors 312 and 314 are received by touch detector 310 and may be conditioned for further processing. For example, touch detector 310 receives the strain measurements output by force sensors 312 and 314 and normalizes the signal. Strains due to temperature may also be accounted for by touch detector 310. Further, touch detector 310 compares the strain measurements received from force sensors 314 and 312 to a signature, such as a model or a precalibrated matrix. In some embodiments, normalized strain measurements from force sensors 312 and 314 are compared to a precalibrated vector. If the normalized strain measurements are sufficiently correlated with the precalibrated vector, then touch input(s) are detected. The precalibrated vector may include the normalized strain measurements for each force sensor 312 and 314 obtained from a cohort of users performing specified actions, such as virtual button presses. The precalibrated vector can be considered to be a signature of a particular touch, such as a press of a virtual power button. In some embodiments, the precalibrated vector may be obtained from one or a few representative devices. In some embodiments, some or all of the precalibrated vector is individually determined for each device. In some embodiments, this comparison of strain measurements to the signature is accomplished by mapping the received strain measurements to corresponding input forces using a precalibrated force transfer matrix. Consequently, the magnitude(s) and location(s) of the force(s) sensed by force sensors 312 and 314 can be determined. The input forces are compared to known forces corresponding to the touch input. If the input forces are sufficiently correlated with the known forces, then touch input(s) are detected. The result of the correlation may be used by touch detector 310 to detect a user touch input and determine a location associated with the user touch input, for example the virtual button(s) pressed.

FIG. 4 is a flow chart depicting an embodiment of method 400 utilizing force sensors for performing touch detection. In some embodiments, processes of method 400 may be performed in a different order, including in parallel, may be omitted and/or may include substeps.

Measurements are received from the force sensors, at 402. Thus, 402 may occur in response to a user's touch input or other physical disturbance to the device. In some embodiments, the measurements are strain measurements. The measurements received may simply be the voltages from each of the sensor(s) corresponding to the force sensors. For example, if each force sensor is an individual strain sensor, then a single strain (voltage) is received from each force sensor at 402. If each force sensor is an integrated sensor such as integrated sensor 200, then ten strain measurements are received from each force sensor at 402, possibly corresponding to strain in different axes or orientations. Also at 402, a temperature measurement may be received. The temperature measurement allows for drifts or other temperature related artifacts to be accounted for in determining whether a touch has been detected.

A signature and the measurements received are used to detect whether there have been user touch input(s), at 404. In some embodiments, the signature is a model of a touch input. In some embodiments, the signature includes a precalibrated matrix. The precalibrated matrix may be a precalibrated force transfer matrix. In some embodiments, the precalibrated matrix is a precalibrated vector (e.g. a j×1 matrix, where j is the number of strain measurements). In some embodiments, the precalibrated vector corresponds to normalized, averaged strain vectors. In such embodiments, the measurements received 402 are normalized and compared to the precalibrated matrix to determine if the strain measurements correspond to a touch.

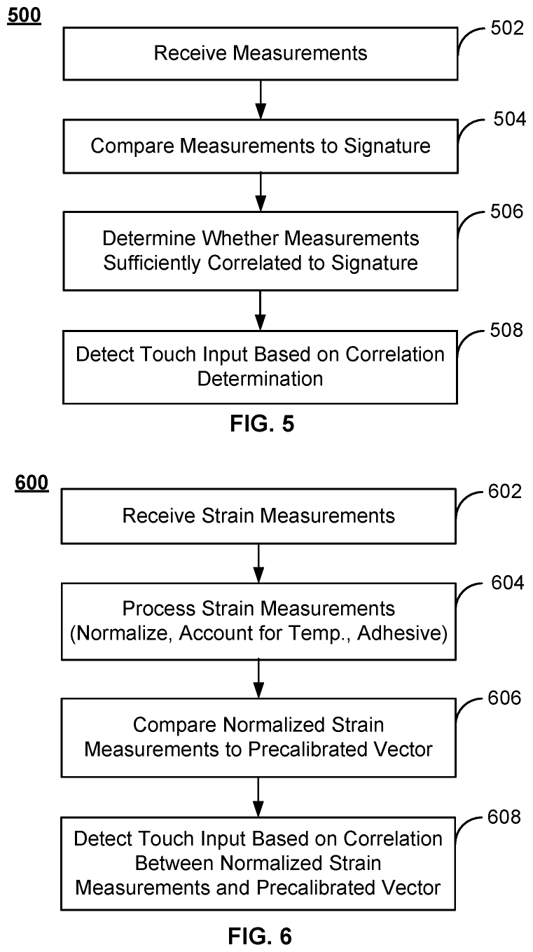

FIG. 5 is a flow chart depicting an embodiment of method 500 utilizing force sensors for performing touch detection. In some embodiments, processes of method 500 may be performed in a different order, including in parallel, may be omitted and/or may include substeps.

Measurements are received from the force sensors, at 502. Thus, 502 may occur in response to a user's touch input or other physical disturbance to the device. In some embodiments, the measurements are strain measurements. If each force sensor is an individual strain sensor, then a single measurement is received from each force sensor at 502. If each force sensor is an integrated sensor such as integrated sensor 200, then multiple measurements are received from each force sensor at 502, possibly corresponding to strain in different axes or orientations. Also at 502, a temperature measurement may be received. The temperature measurement allows for drifts or other temperature related artifacts to be accounted for in determining whether a touch has been detected.

The measurements received at 502 are compared to a signature, at 504. In some embodiments, the signature is a model of a touch input. For example, measurements (e.g. strain measurements) that would correspond to a touch input may be generated by a model and compared to the measurements received. In some embodiments, the signature includes a precalibrated matrix. In some embodiments, the precalibrated matrix is a precalibrated vector corresponding to calibration measurements received during a calibration for the device. For example, the precalibrated vector corresponds to strain measurements obtained at manufacturing from each device or from representative device(s). In some embodiments, the comparison at 504 is performed by mapping the measurements to input forces using a precalibrated force transfer matrix. The input forces may be compared to known input forces obtained during calibration of the device or representative devices.

It is determined whether a sufficient correlation exists between the signature and the measurements, at 506. For example, it may be determined whether the correlation between the measurements and the signature meet or exceed a threshold. If so, then touch input(s) are detected, at 508.

Thus, utilizing measurements from force sensors, touch inputs may be detected. Because a signature is utilized, the detection at 508 may more accurately distinguish touch inputs from inadvertent touches or flexing of the device. Thus, performance may be improved.

FIG. 6 is a flow chart depicting an embodiment of method 600 utilizing strain sensor for performing touch detection. In some embodiments, processes of method 600 may be performed in a different order, including in parallel, may be omitted and/or may include substeps.

Strain measurements are received from the force sensors, at 602. Thus, 602 may occur in response to a user's touch input or other physical disturbance to the device. The strain measurements received may simply be the voltages from each of the strain sensor(s) corresponding to each of the force sensors. For example, if each force sensor is an individual strain sensor, then a single strain (voltage) is received from each force sensor at 602. If each force sensor is an integrated sensor such as integrated sensor 200, then ten strain measurements are received from each force sensor at 602, possibly corresponding to strain in different axes or orientations. Also at 602, a temperature measurement may be received. The temperature measurement allows for drifts or other temperature related artifacts to be accounted for in determining whether a touch has been detected.

The strain measurements received at 602 are processed at 604. At 604 temperature may be accounted for. In some embodiments, temperature changes of a few degrees Celsius can result in the thermal expansion of the portion of the device for which force sensors measure strain. This thermal expansion may be significantly larger than any change in strain due to input force(s) (e.g. due to a touch). The thermal effects also typically occur on a much longer time scale than user input force(s) (touch inputs). In some embodiments, thermal effects are accounted for using the temperature measurement provided at 602 and a model for thermal effects obtained during calibration. In some embodiments, the model includes nonlinear temperature terms. In some embodiments, the small time scale of touch inputs may also be accounted for, for example, by filtering for higher frequency signals and/or accounting for the low frequency temperature variations in the model. Thus, the temperature induced expansion of the force sensor or section of the device to which the force sensor is attached may be modeled. Using this model and the temperature received at 602, the temperature induced expansion is removed from the strain measurements or otherwise accounted for at 604.

In some embodiments, the unit-to-unit variations in mounting of the force sensors are accounted for at 604. For example, small differences in the amount of glue used to attach force sensors to the device may result in variations in the strain measurements, particularly if there are multiple strain sensors in the same axial orientation integrated into the force sensor. Such variations may affect the gain for the strain sensors. Thus, a gain calibration for each device may be carried out at manufacturing and incorporated into the processing of the strain measurements. The strain measurements are also normalized at 604. Thus, variations in the magnitude of the input force a user applies when providing a touch input to the device may be accounted for.

The normalized strain measurements are compared to a signature, at 606. In some embodiments, the signature includes a precalibrated vector. More specifically, the strain measurements received at 602 may be considered to be an n-dimensional vector (S), where n is the number of strain measurements (e.g. the number of strain sensors). The precalibrated vectors are also n-dimensional because the precalibrated vectors correspond to strains received during calibration. The precalibrated vectors may also be normalized and have temperature induced strains and variations in adhesive accounted for. The precalibrated vectors may be determined at manufacturing from a cohort including a variety of users (e.g. old and young, large and small, male and female, etc.) carrying out specific functions, such as swipes, virtual button presses and/or other physical disturbances to particular devices. In some embodiments, the precalibrated vectors also account for unit-to-unit variations in mounting of the force sensors.

If the normalized strain measurements sufficiently match the precalibrated vector(s), then a touch input is detected at 608. In some embodiments, 608 includes determining whether a sufficient correlation is present and detecting the touch input if it is determined that the sufficient correlation present in a manner analogous to 506 and 508 of method 500. In the example above, an n-dimensional box of specific size (e.g. corresponding to a 0.8-1.2 correlation of each dimension) may enclose the n-dimensional precalibrated vector. Alternatively, an n-dimensional box may enclose the vertex of the n-dimensional vector. If the normalized n-dimensional vector for the strain measurements falls within this box, a sufficient correlation is present and a touch input is detected at 608. If the normalized n-dimensional vector for the strain measurements does not fall within this box, then a touch input is not detected. Thus, using method 600, strain measurements may be utilized to detect user touch inputs to a device. In some embodiments, the normalized strain measurements can be considered the superposition of multiple precalibrated vector(s), corresponding to multiple simultaneous touches. 608 then determines the correlation against each possible vector(s), determining if there is sufficient correlation for multiple simultaneous touches. In other embodiments, there are specific precalibrated vector(s) corresponding to the presence of multiple touches, without reliance on the principle of superposition of the strain vectors. This can be particularly important if the surface to which the sensor is attached is nonuniform, for example, in a metal housing with co-molded plastic.

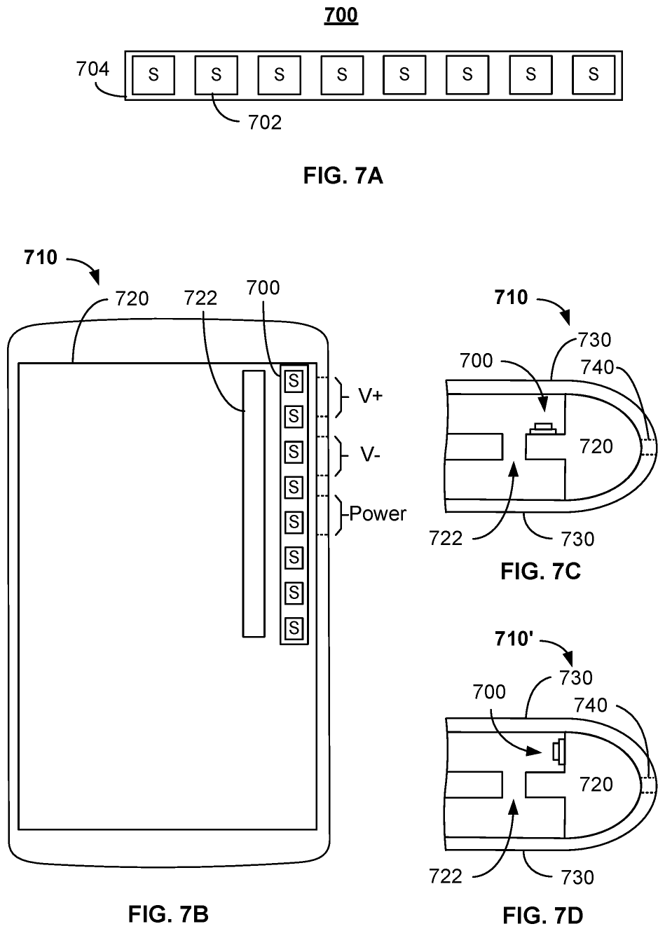

For example, FIGS. 7A-7D depict embodiments of a device using strain sensors for touch input detection. For simplicity, only portions of the device and strain sensors are shown. FIG. 7A depicts the force sensor bar 700. Force sensor bar 700 includes force sensors 702 and circuit board 704. Circuit board 704 provides mechanical stability and electrical connection for force sensors 702. In some embodiments, circuit board 704 is approximately fifty millimeters long. In some embodiments, force sensors 702 are integrated sensors, such as integrated sensors 200. Thus, integrated sensors 702 may include eight strain sensors distributed in pairs at the edges, an xy sensor and an additional strain sensor in the central region, and a temperature sensor. In the embodiment shown, force sensor bar 700 includes eight integrated sensors. In other embodiments, another number of integrated sensors and/or other integrated sensors may be used. In some embodiments, additional mechanisms for measuring force may be included in one or more force sensors. For example, a piezoelectric force sensor may be used.

FIG. 7B depicts an embodiment of a device 710 in which force sensor bar 700 may be mounted. In the embodiment shown, device 710 is a mobile phone. In other embodiments, force sensor bar 700 may be utilized in another device. In some embodiments, a touch detector (not shown) analogous to touch detector 310 is included in device 710. Device 710 has an internal frame 720, such as a midframe, to which force sensor bar 700 is mounted. In some embodiments, force sensors 720 may be mounted directly on device 710 and circuit board 704 omitted. However, such mounting may present manufacturing challenges and electrical connection to force sensors 702 would be made in another manner. In the embodiment shown, frame 720 has an aperture 722 therein. Aperture 722 allows the section of frame 720 to which sensor bar 700 is connected to be more flexible. Thus, flexing and/or expansion due to users pressing virtual buttons on the side of device 710 may be enhanced. As a result, force sensors 702 may provide an increased signal.

Also shown in device 710 are virtual buttons V+, V− and Power. These virtual buttons may be at the side of device 710, instead of the front face of the display. Dashed lines in device 710 indicate the size of virtual buttons V+, V− and Power. In some embodiments, the regions corresponding to the virtual buttons extend across multiple force sensors 902. Thus, the virtual buttons are regions configured to receive input forces. A push of the virtual buttons applies force(s) substantially in a direction perpendicular to the long axis of force sensor bar 700. A user pressing one or more of the virtual buttons (e.g. providing touch inputs to one or more of the virtual buttons) generally results in nonzero strains being measured by all of force sensors 702, with a specific strain signature to distinguish which virtual button is (or buttons are) being actuated by the user.

FIGS. 7C and 7D depict a portion of devices 710 and 710′, indicating two embodiments of locations which force sensor bar 700 may occupy. Also shown in FIGS. 7C and 7D are cover 730 and optional seal 740. In some embodiments, one or both of covers 730 are displays. Seal 740 is present if devices 710 and 710′ include a front cover and a back cover. If a single wraparound cover is used, then seal 740 is omitted. Device 710 includes force sensor bar 700 mounted to a ledge of frame 720 that faces the front (or back) display. Device 710′ includes force sensor bar 700 mounted to a ledge of frame 720 that is perpendicular to the front (or back) display. In other embodiments, force sensor(s) 702 and/or force sensor bar 700 may be mounted in another manner. For example, covers 730 may include recesses in which force sensors 702 may be individually mounted.

For example, to provide the signature used in method 600, a user initiated force is provided. A user may press a virtual power button. The resulting strains are measured by the force sensors. The virtual button press and the measurement of the strain are repeated. The user may press a virtual power button ten times, virtual volume increase button ten times, and virtual volume decrease button ten times as part of the calibration process. This may be repeated for other users. The resulting strain measurements for presses of each virtual button may be averaged and normalized. A first precalibrated vector corresponds to a virtual power button press, the second precalibrated vector corresponds to a virtual volume increase button press and the third precalibrated vector corresponds to a virtual volume decrease button press. These precalibrated vectors are used in the signature.

To detect touch inputs, strain measurements are received from force sensors 702, at 602. If integrated sensors, such as integrated sensor 200, are used for force sensors 702, ten measurements may be received from each sensor at 602. However, because of the manner in which the strain sensors are mounted in the force sensor, only six strain measurements are independent: one measurement for each of the four sides, the xy strain measurement and the strain measurement form the center of the integrated sensor. Thus, in some embodiments, six strain measurements per force sensor 702 may be used.

These eighty (or forty-eight) strain measurements are processed at 604, including normalizing the strain measurements. The normalized strain measurements are compared to the precalibrated vectors corresponding to a virtual power button press, a virtual volume increase button press and a virtual volume decrease button, at 606.

If the normalized measurements are sufficiently close to one or more of the precalibrated vectors, then a touch is detected, at 608. For example, if the normalized strain measurements are within a particular distance in eighty (or forty-eight) dimensional space, then touch input(s) of the corresponding button(s) are detected. For example, if the normalized strain measurements fall within the boxes discussed above corresponding to the precalibrated vector(s), then the virtual button is considered pressed. In some embodiments, if the normalized strain measurements are sufficiently correlated with multiple precalibrated vectors (e.g. V+ and V−), then multiple virtual buttons are considered pressed. Further, because the dimension of the precalibrated vectors and normalized strain measurements are high, the signature of a button press (e.g. precalibrated vectors) is nearly unique. Thus, false positive may be limited. Consequently, the detection of touch in puts corresponding to virtual button presses may be improved.

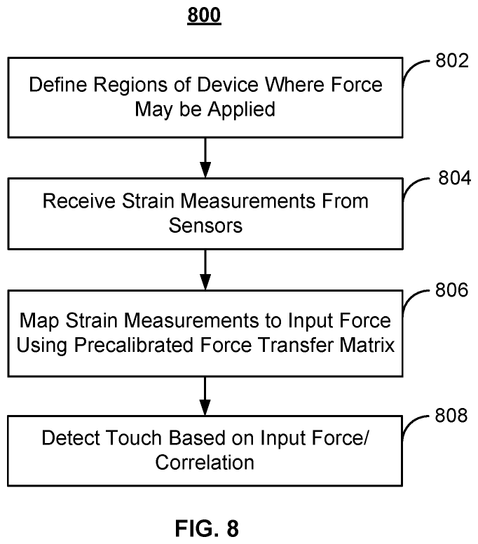

FIG. 8 is a flow chart depicting an embodiment of method 800 for detecting a touch for a device. In some embodiments, processes of method 800 may be performed in a different order, including in parallel, may be omitted and/or may include substeps. Method 800 allows for determination of the magnitudes and locations of the forces applied to a device using strain measurements.

Regions of the device where a force may be applied are defined, at 802. These regions may correspond to virtual buttons, to sections of a housing, to the force sensors themselves, sections of a display and/or to some other feature. For example, in the case of virtual buttons, the regions may be the virtual buttons rendered on the display. In some embodiments, the regions may be smaller or larger than buttons as-rendered. In some embodiments, the number of regions defined at 802 are the same as the number of force sensors. In other embodiments, the number of regions defined differs from the number of force sensors. In addition, the size of the regions defined at 802 generally differs from the size of the force sensors. For example, the regions defined at 804 may be larger than the force sensors.

Strain measurements are received from the force sensors, at 804. Thus, 804 occurs in response to a user touch input or other physical disturbance to the device. The strain measurements received may simply be the voltages from each of the strain sensor(s) corresponding to each of the force sensors. For example, if each force sensor is an individual strain sensor, then a single strain (voltage) is received from each force sensor at 804. If a force sensor is an integrated sensor such as integrated sensor 200, then ten strain measurements are received from the force sensor at 804. Also at 804, a temperature measurement may be received. The temperature measurement allows for drifts or other temperature related artifacts to be accounted for in determining whether a touch has been detected.

A precalibrated force transfer matrix is used to map the strain measurements to input force(s) applied to one or more of the regions, at 806. More specifically, the strain measurements received at 404 may be considered to be an n-dimensional vector (S), where n is the number of strain measurements (e.g. the number of strain sensors). The input force(s) applied to each region may be an m-dimensional vector (F), where m is the number of regions. In such embodiments, X is the n by m matrix that satisfies: SX=F. Alternatively, X may be defined as the m by n matrix that satisfies S=XF. The precalibrated force transfer matrix may be determined during calibration. Further, the precalibrated matrix or other signal processing performed as part of the mapping may also account for temperature, as described above in method 800. The mapping at 806 provides the magnitude(s) and location(s) of input force(s) corresponding to the strain measurements.

It is determined whether a touch input is detected using the input force(s), at 808. Thus, 806 and 808 may be considered to perform 504, 506 and 508 of method 500. In some embodiments, 808 includes comparing the input force(s) determined at 406 with known input forces. The known input forces may be obtained from a cohort including a variety of users (e.g. old and young, large and small, male and female, etc.) carrying out specific functions, such as swipes, virtual button presses and/or other physical disturbances. In some embodiments, the known input forces may be obtained by the user individually carrying out an analogous calibration procedure on the device. If the input force(s) obtained at 806 sufficiently match the known input forces, then a touch is detected at 808. In the example above, an m-dimensional box of specific size (e.g. corresponding to a 0.8-1.2 correlation of each dimension) may enclose the m-dimensional vector corresponding to the known input forces. If the m-dimensional vector for the input force(s) determined at 808 falls within this box, a sufficient correlation is present and a touch is detected. If the m-dimensional vector for the input forces determine at 808 does not fall within this box, then a touch is not detected. Thus, using method 800, strain measurements may be utilized to detect touch inputs to a device.

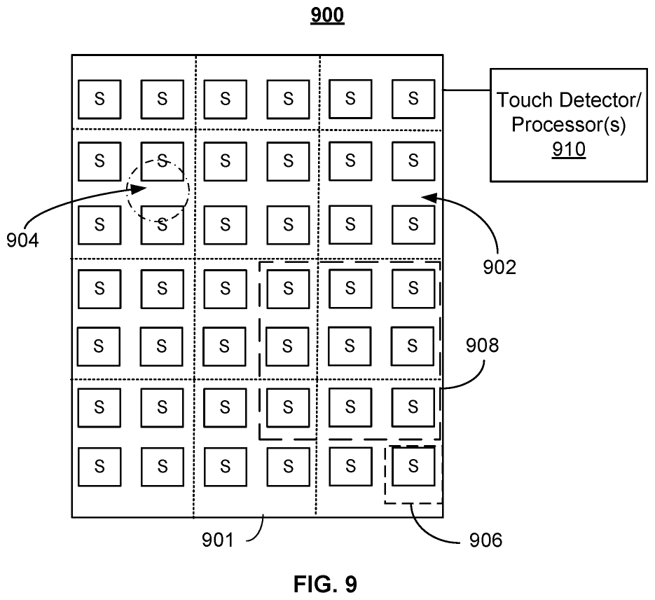

For example, FIG. 9 depicts an embodiment of device 900 utilizing strain sensors for touch input detection. Method 400, 500 and 800 may be used in connection with device 900. System 900 is part of a device utilizing touch inputs. Thus, system 900 may be part of a kiosk, an ATM, a computing device, an entertainment device, a digital signage apparatus, a mobile phone, a tablet computer, a point of sale terminal, a food and restaurant apparatus, a gaming device, a casino game and application, a piece of furniture, a vehicle, an industrial application, a financial application, a medical device, an appliance, and any other objects or devices having surfaces for which a touch input is desired to be detected.

System 900 includes touch detector 910 that is analogous to touch detector 310 and is connected with touch surface 901. Touch surface 901 can, but need not be flat. For example, touch surface may include the edge of a waterfall display for a mobile phone, a display and side of a mobile phone or other surface. In some embodiments, touch surface 901 can occupy the entire outer surface of the device. Force sensors (labeled S) are distributed across touch surface 901. In some embodiments, each force sensor S is an integrated sensor such as integrated sensor 200. Thus, multiple strain measurements may be provided from a single force sensor. In other embodiments, each force sensor includes a single strain sensor. In other embodiments, additional mechanisms for measuring force may be included in one or more force sensors. For example, a piezoelectric force sensor may be used.

Touch surface 901 has been divided into regions. For the sake of explanation, different possible regions 902, 904, 906 and 908 are shown. Each region 902 (separated by dotted lines) includes multiple force sensors S. However, the number of force sensors per region is not constant. For example, some regions 902 include four force sensors, while the top regions 902 include two force sensors. Regions 902 cover touch surface 901. Region 904 (circular having a dashed/dotted line) corresponds to a particular virtual button. Although only one region 904 is shown, multiple regions can be defined. For example, region 904 may be one virtual button of a nine button numeric key pad. However, in such embodiments, regions 904 do not occupy all of touch surface 901. Region 906 corresponds to a single force sensor. Thus, to cover touch surface 901, the same number of regions 906 as force sensors would be utilized. Region 908 covers a larger number of force sensors. Thus, various regions might be defined.

To detect a touch input using method 800, touch surface 901 is divided into regions at 802. For the purposes of explanation, regions 902 are used. Strain measurements are received from the force sensors at 804. In some embodiments, all of the force sensors are utilized. In other embodiments, only a subset of force sensors may be used. If each force sensor is an integrated sensor such as integrated sensor 200, then four hundred and twenty strain measurements are received by touch detector 910 at 804. In addition, forty-two temperature measurements may be received by touch detector 910. Using the precalibrated matrix, touch detector 910 maps the strain measurements from force sensors S to input forces, at 806. For example, suppose a user pressed on labeled region 902. Some or all of the force sensors S measure nonzero strains. Then at 806, the four hundred and twenty strain measurements (corrected using the temperature measurements) are mapped to indicate the magnitude and the location (region 902) of the force corresponding to the user's touch. A touch input may then be detected at 808.

Thus, using method 800, touch detector 910 can determine the magnitude and location (e.g. region 602) of a force corresponding to a set of strain measurements. Touch inputs for touch surface 901 may be detected.

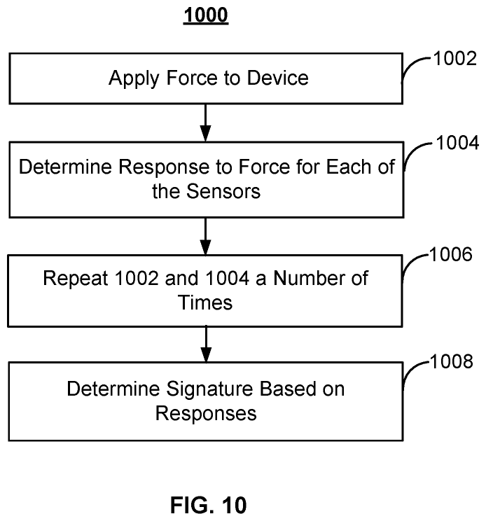

FIG. 10 is a flow chart depicting an embodiment of method 1000 for providing a signature. In some embodiments, processes of method 1000 may be performed in a different order, including in parallel, may be omitted and/or may include substeps. In some embodiments, in which a known force is utilized for method 1000, a precalibrated force transfer matrix is determined. This is because the strain measurements can be mapped to forces for which the magnitude, direction (toward the device) and location are known. In other embodiments, the signature determined using method 1000 results in a precalibrated vector to which strain measurements might be directly compared.

A particular force is applied to at least one region of the device, at 1002. The force(s) are applied to one or more of the regions that are defined as configured to receive forces. For example, the force may be applied to region(s) 902, 904, 906 and 908 and/or to virtual buttons V+, V− and Power of device 710. In some embodiments, the device is supported such that the device is motionless during application of the load. In some embodiments, multiple forces are applied in multiple locations. In other embodiments, a single force is applied at a single location.

A response to the applied force(s) for each of the force sensors is determined, at 1004. Thus, force sensors capture the strain and output the corresponding strain measurements. For integrated sensors, such as integrated sensor 200, multiple strain measurements (e.g. one per strain sensors) are received for each integrated sensor at 1004. Because the device may flex during application of the force at 1002, nonzero strain measurements are generally received from a force sensor even if a single force is applied at a location on the device relatively distant from the force sensor.

The application of the force and the measurement of the strain at 1002 and 1004 are repeated, at 1006. In some embodiments, the application of the force and measurement of the strain are repeated not only for a single location, but for multiple locations on the device. Further, application of the force(s) may be repeated for multiple users and/or multiple representative devices. Thus, at 1002, 1004 and 1006 sufficient data are collected to have information on both the applied force and the resulting strain measurements.

The signature is determined based on the response for each force sensor and each applied force, at 1008. In some embodiments, the strain measurements determined at 1004 and 1006 are averaged. In some embodiments, the strain measurements are also normalized. Thus, the signature may be determined based on normalized and/or average strains.

For example, the signature provided using method 800 utilizes normalized strain measurements and forces for which the magnitude is unknown. In such embodiments, the signature corresponds to the precalibrated vector to which strains are compared in method 600. In some such embodiments, the force applied at 1002 may be user initiated. For example, a user may press a virtual power button at 1002. The resulting strains are measure by the force sensors at 1004. The virtual button press and the measurement of the strain at 1002 and 1004 are repeated, at 1006. The user may press a virtual power button ten times, press a virtual volume increase button ten times, and press a virtual volume decrease button ten times as part of 1002, 1004 and 1006. This process may be repeated for other users at 1006. Thus, a cohort of users may provide touch input for calibrations. The resulting strain measurements for presses of each virtual button may be averaged and normalized. The signature provided in this embodiment may be precalibrated vectors of averaged, normalized strain measurements. In the example above, a first precalibrated vector corresponds to a virtual power button press, the second precalibrated vector corresponds to a virtual volume increase button press and the third precalibrated vector corresponds to a virtual volume decrease button press. These precalibrated vectors may be compared to normalized strain measurements during use to determine whether one or more of the virtual buttons is pressed. This calibration process may be performed for a particular number of devices at manufacture, and then generalized to other analogous devices. In addition, a gain calibration to account for device-by-device variations may also be performed.

In another example, determining a signature may be considered to include providing a precalibrated force transfer matrix used in mapping strains to input forces in method 800. To provide the precalibrated force transfer matrix, known forces are used for method 1000. For example, a force corresponding to a 5 g weight may be applied to a particular location, at 1002. Also at 1002, the device is supported at a particular number of points. Consequently, it is known what the applied forces are and that the device is not undergoing any acceleration (e.g. is stationary). In some embodiments, the input force(s) applied are defined as positive and oriented toward the device. The strain measurements resulting from the known force are collected from the force sensors at 1004. The application of the known force and the measurement of the strain at 1002 and 1004 are repeated, at 1006. Thus, the known force may be applied to a first region a particular number times, and to all of the remaining regions of the device a number times for each region at 1002, 1004 and 1006. For example, the same 5 g weight may be reapplied to the same location a ten times at 1006. The 5 g weight may then be applied ten times to other locations also at 1006. The process may also be repeated for other forces (e.g. a 10 g weight, a 15 g weight, etc.) at 1006. The strain measurements may be averaged. Based on the strain measurements, the known forces and their location, the structure of the device (e.g. the housing), and the knowledge that the device is static, a corresponding precalibrated force transfer matrix determined at 1008. In such embodiments, the precalibrated force transfer matrix determined at 1008 correlates strain measurements to absolute forces of known magnitudes and locations.

Although the foregoing embodiments have been described in some detail for purposes of clarity of understanding, the invention is not limited to the details provided. There are many alternative ways of implementing the invention. The disclosed embodiments are illustrative and not restrictive.

What is claimed is:

1. A system, comprising:
a plurality of force sensors;
a processor configured to:
receive a plurality of measurements from the plurality of force sensors;
compare the plurality of measurements to a signature corresponding to at least one input force applied to at least one of a plurality of regions configured to receive a force;
determine that a correlation between the plurality of measurements and the signature exceeds a threshold; and
detect a touch input in response to the determination; and
a memory coupled to the processor and configured to provide the processor with instructions.

2. The system of claim 1, wherein the force sensors include a plurality of strain sensors and wherein the plurality of measurements include a plurality of strain measurements.

3. The system of claim 2, wherein the signature is a precalibrated vector corresponding to a plurality of precalibrated strain measurements.

4. The system of claim 3, wherein the processor is further configured to:
normalize the plurality of strain measurements, the precalibrated vector being a normalized vector.

5. The system of claim 1, wherein the plurality of regions include a first number of regions and wherein the plurality of forces sensors include a second number of force sensors, the first number being different from the second number.

6. The system recited in claim 1, wherein the plurality of force sensors includes a plurality of integrated strain sensors.

7. The system of claim 6, wherein each of the plurality of integrated strain sensors includes a first plurality of sensors for measuring strain along a first axis, a second plurality of sensors for measuring strain along a second axis, and at least one cross sensor, the second axis being perpendicular to the first axis,

8. The system of claim 7, wherein the system is integrated into a mobile phone having a frame, the plurality of force sensors being mounted to the frame.

9. The system of claim 1, wherein the signature is a precalibrated force transfer matrix and wherein the processor being configured to compare the plurality of measurements to the signature further includes the processor being configured to:
use the precalibrated force transfer matrix to map the plurality of measurements to at least one input force applied to each of the plurality of regions; and
compare the at least one input force to a known force corresponding to the touch input.

10. A method, comprising:
receiving a plurality of measurements from a plurality of force sensors, the plurality of force sensors corresponding to a plurality of regions of a device, the plurality of regions being configured to receive a force;
comparing the plurality of measurements to a signature corresponding to at least one input force applied to at least one of the plurality of regions;
determining that a correlation between the plurality of measurements and the signature exceeds a threshold; and
detecting a touch input in response to the determination.

11. The method of claim 10, wherein the plurality of measurements include a plurality of strain measurements.

12. The method of claim 11, wherein the signature is a precalibrated vector corresponding to a plurality of calibration strain measurements.

13. The method of claim 12, further comprising:
normalizing the plurality of strain measurements, the precalibrated vector being a normalized vector.

14. The method of claim 12, further comprising:
providing the precalibrated vector, the providing the precalibrated vector further including
applying a user initiated force to each of the plurality of regions a particular number of times for a plurality of users;
receiving the plurality of calibration strain measurements corresponding to the user initiated force from the plurality of force sensors for the plurality of regions for the particular number of times; and
normalizing the plurality of calibration strain measurements.

15. The method of claim 10, wherein the signature is a precalibrated force transfer matrix and wherein the comparing the plurality of measurements to the signature further includes:
using the precalibrated force transfer matrix to map the plurality of measurements to at least one input force applied to each of the plurality of regions; and
comparing the at least one input force to a known force corresponding to the touch input.

16. The method of claim 15, further comprising:
providing the precalibrated force transfer matrix, the providing the precalibrated force transfer matrix further including
applying a particular force to at least one point;
determining a response to the particular force from each of at least one of the plurality of force sensors;
repeating the applying the particular force and determining the response for the at least one of the plurality of force sensors for a plurality of locations and a plurality of particular forces; and
determining the precalibrated force transfer matrix based on the response for each particular force.

17. A computer program product, the computer program product being embodied in a non-transitory computer readable storage medium and comprising computer instructions for:
receiving a plurality of measurements from a plurality of force sensors, the plurality of force sensors corresponding to a plurality of regions of a device, the plurality of regions being configured to receive a force;
comparing the plurality of measurements to a signature corresponding to at least one input force applied to at least one of the plurality of regions;
determining that a correlation between the plurality of measurements and the signature exceeds a threshold; and
detecting a touch input in response to the determination.

18. The computer program product of claim 17, wherein the signature is a precalibrated vector corresponding to a plurality of calibration strain measurements and wherein the plurality of measurements include a plurality of strain measurements.

19. The computer program product of claim 18, wherein the computer program product further includes computer instructions for:
normalizing the plurality of strain measurements, the precalibrated vector being a normalized vector.

20. The computer program product of claim 17, wherein the signature is a precalibrated force transfer matrix and wherein the instructions for comparing the plurality of measurements to the signature further include instructions for:
using the precalibrated force transfer matrix to map the plurality of measurements to at least one input force applied to each of the plurality of regions; and
comparing the at least one input force to a known force corresponding to the touch input.
